(19) United States
(12) Patent Application Publication
(10) Pub. No.: US 2022/0293504 A1
(43) Pub. Date: Sep. 15, 2022

(54) SEMICONDUCTOR PACKAGING STRUCTURE, METHOD, DEVICE AND ELECTRONIC PRODUCT

(71) Applicant: Yibu Semiconductor Co., Ltd., Shanghai (CN)

(72) Inventor: Weiping LI, Shanghai (CN)

(21) Appl. No.: 17/693,357

(22) Filed: Mar. 12, 2022

(30) Foreign Application Priority Data
Mar. 12, 2021 (CN) 202110269375.8
Mar. 12, 2021 (CN) 202110272185.1

(51) Int. Cl. H01L 23/498; H01L 23/00; H01L 23/08

(52) U.S. Cl. CPC H01L 23/49822; H01L 24/08; H01L 23/08; H01L 24/32; H01L 24/83; H01L 2224/08225; H01L 2224/32225; H01L 2224/8385

(57) ABSTRACT

The application provides a semiconductor packaging structure, a semiconductor packaging method, a semiconductor packaging device and an electronic product. The semiconductor packaging structure comprises a substrate, at least one packaged component, a redistribution layer and a passivation layer. The substrate has at least one groove and the at least one packaged component is fixed in the at least one groove in one-to-one correspondence. Each packaged component is separated from a corresponding groove, in which the package component is disposed, by insulating materials. The at least one packaged component has first bonding pads on at least one active surface facing away from the substrate and are flush. The redistribution layer is formed over the at least one active surface. The substrate includes a semiconductor material or insulating material with a thermal expansion coefficient that is the same as or similar to that of a base semiconductor material in the packaged component.

### CROSS REFERENCE TO RELATED APPLICATIONS

The present application claims the benefit of priority under the Paris Convention to Chinese Patent Application No. 202110269375.8, filed Mar. 12, 2021, entitled “Semiconductor Packaging Structure, Method, Device and Electronic Product,” and Chinese Patent Application No. 202110272185.1, filed Mar. 12, 2021, entitled “Semiconductor Packaging Structure, Method, Device and Electronic Product,” each of which is incorporated herein by reference in its entirety. The present application is related to co-pending US Patent Application Attorney Docket No. YB019-05US, entitled “Semiconductor Packaging Structure, Method, Device and Electronic Product,” filed on even date herewith, which is incorporated herein by reference in its entirety.

### FIELD OF THE INVENTION

The present application relates to the technical field of semiconductor manufacturing, in particular to a semiconductor packaging structure, a semiconductor packaging method, a packaged semiconductor device and an electronic product including same.

### BACKGROUND

In a typical semiconductor packaging process, a component (e.g., a die, also referred to as die) needs to be packaged, generally by fixing the component on a substrate, a frame (e.g., lead frame) or an interposer, and then packaging the component in a series of processes such as interconnect formation and molding encapsulation, to obtain a packaged semiconductor device.

### SUMMARY

Certain embodiments are directed to providing a semiconductor packaging structure, a semiconductor packaging method, a packaged semiconductor device and an electronic product including same.

In certain embodiments, a semiconductor package structure comprises a substrate having at least one groove, at least one packaged component fixed in the at least one groove, a redistribution layer and a passivation layer. In some embodiments, the at least one groove is formed in the substrate and corresponds, respectively, to the at least one groove, and each packaged component is fixed in a corresponding one of the at least one groove.

In some embodiments, an active surface of the packaged component faces away from the substrate, the packaged component and the corresponding groove, in which the package component is disposed, are separated by insulating materials. Each packaged component is provided with first bonding pads located on the active surface of the packaged component, and the surfaces of the first bonding pads, which faces away from the substrate, are flush.

In some embodiments, the redistribution layer is positioned on one side of the packaged component opposite to (or facing away from) the substrate, a plurality of second bonding pads are formed on a first surface of the redistribution layer, a plurality of third bonding pads are formed on a second surface, opposite to the first surface, of the redistribution layer, the second bonding pads are in electrical contact with respective ones of the first bonding pads in one-to-one correspondence, conductors in the redistribution layer are separated from each other by insulating materials, and the redistribution layer is further provided with routing wires electrically connected with the second bonding pads and the third bonding pads.

In some embodiments, the passivation layer is positioned on one side of the redistribution layer facing away from the substrate.

In some embodiments, the substrate is formed by a semiconductor material or an insulating material, the thermal expansion coefficient of the substrate is the same as or similar to that of the semiconductor material in the packaged component, and the redistribution layer is formed by a wafer manufacturing process.

In some embodiments, a semiconductor packaging method comprises forming at least one groove in a substrate; and fixing at least one packaged component in the at least one groove, such that each packaged component is fixed in a corresponding one of the at least one groove and the active surface of the packaged component faces away from the substrate. In some embodiments, the packaged component is separated from the groove, in which the packaged component is fixed, by one or more insulating materials. Each packaged component is provided with first bonding pads located on the active surface of the packaged component, and the surfaces of the first bonding pads, which faces away from the substrate, are flush.

In some embodiments, the semiconductor packaging method further comprises forming a flat surface where the first bonding pads are exposed.

In some embodiments, semiconductor packaging method further comprises forming a redistribution layer. In some embodiments, a plurality of second bonding pads are formed on a first surface of the redistribution layer, and a plurality of third bonding pads are formed on a second surface of the redistribution layer, which is opposite to the first surface. In some embodiments, the second bonding pads are in electrical contact with respective ones of the first bonding pads, conductors in the redistribution layer are separated from each other by insulating materials, and the redistribution layer is also provided with routing wires which are electrically connected with the second bonding pads and the third bonding pads.

In some embodiments, the semiconductor packaging method further comprises forming a passivation layer.

In some embodiments, the substrate is formed of a semiconductor material or an insulating material, and the substrate has the same or similar thermal expansion coefficient as the semiconductor material in the packaged component.

In some embodiments, a semiconductor packaging structure including or made using the foregoing is provided.

In some embodiments, an electronic product comprises the foregoing semiconductor device.

The embodiments provide several benefits, as compared with conventional packaging technologies, as discussed in the following.

Because the thermal expansion coefficients of the semiconductor material in the packaged component and the substrate are equal or close (for example, the two are made of a same semiconductor material), and the thermal expansion coefficient of at least one insulating material in the redistribution layer is the same or close to that of the insulating material in the packaged component, after the packaging is completed, the warpage of the semiconductor packaging structure generated due to changes in temperature is relatively small, resulting in improved yield and electrical and mechanical reliability of the semiconductor device. Also, in some embodiments, the semiconductor substrate provides better heat dissipation than the molding material of conventional packaging forms.

Furthermore, as the redistribution layer is formed using existing semiconductor manufacturing processes (FAB process and wafer manufacturing process), the manufacturing process is mature, and the line-width and the line-distance in the redistribution layer are narrower or shorter, so that the interconnection density is higher, and the area of the semiconductor packaging structure is smaller.

### BRIEF DESCRIPTION OF THE DRAWINGS

FIG. 1a and 1b are schematic structural diagrams of two semiconductor package structures according to some embodiments.

FIG. 2 is a schematic flow chart of a semiconductor packaging method according to some embodiments.

FIGS. 3a to 3g are schematic product states of the semiconductor package structure shown in FIG. 1a at different stages of a packaging process according to some embodiments.

FIGS. 4a to 4g are schematic product states of the semiconductor package structure shown in FIG. 1b at different stages of a packaging process according to some embodiments.

In the drawings, 1 denotes a substrate; 10 denotes a groove; 111 or 112 denotes an insulating material; 21 or 22 denotes an packaged component; 211 or 221, denotes a first pad; 3 denotes a redistribution layer; 31 denotes a second pad; 32 denotes a third pad; 33 denotes routing; 4 denotes a passivation layer; 5 denotes an electrode structure.

### DETAILED DESCRIPTION OF THE EMBODIMENTS

In this application, it will be understood that terms such as “including” or “having,” or the like, are intended to indicate the presence of the disclosed features, numbers, steps, acts, components, parts, or combinations thereof, but do not preclude the presence or addition of one or more other features, numbers, steps, acts, components, parts, or combinations thereof.

It should be noted that the embodiments and features of the embodiments described herein may be combined with each other without conflict. Some embodiments will be described in detail below with reference to examples shown in the attached drawings.

Some embodiments provide a semiconductor package structure, comprising: a substrate having at least one groove, at least one packaged component fixed in the at least one groove, a redistribution layer, and a passivation layer. The at least one groove is formed in the substrate and corresponds, respectively, to the at least one groove, and each packaged component is fixed in a corresponding one of the at least one groove. An active surface of the packaged component faces away from the substrate, and the packaged component and the corresponding groove, in which the package component is disposed, are separated by insulating materials. Each packaged component is provided with first bonding pads located on the active surface of the packaged component, and the surfaces of the first bonding pads, which faces away from the substrate, are flush. The redistribution layer is positioned on one side of the packaged component opposite to (or facing away from) the substrate, a plurality of second bonding pads are formed on a first surface of the redistribution layer, a plurality of third bonding pads are formed on a second surface, opposite to the first surface, of the redistribution layer, the second bonding pads are in electrical contact with respective ones of the first bonding pads in one-to-one correspondence, conductors in the redistribution layer are separated from each other by insulating materials, and the redistribution layer is further provided with routing wires electrically connected with the second bonding pads and the third bonding pads. The passivation layer is positioned on one side of the redistribution layer facing away from the substrate. The substrate is formed by a semiconductor material or an insulating material, the thermal expansion coefficient of the substrate is the same as or similar to that of the semiconductor material in the packaged component, and the redistribution layer is formed by a wafer manufacturing process.

In some embodiments, each packaged component is placed in a corresponding groove or recess formed in the substrate, and the top (e.g., active) side of the packaged component is covered by a redistribution layer. The substrate and the base material in the packaged component are both semiconductor materials or insulating materials having the same thermal expansion coefficient or similar thermal expansion coefficients.

By referring to two elements as having “the same semiconductor material” in this application, it is to indicate that they include semiconductor materials of the same chemical composition, e.g., both are formed of silicon material, or both are formed of gallium arsenide material, etc. However, these semiconductor materials are not limited to having the same uniformity, purity, density, crystalline state, or the like.

For example, a semiconductor material in the substrate is the same as a base semiconductor material in the packaged component.

As another example, the semiconductor material in the packaged component is silicon or gallium arsenide, and the material of the substrate is engineered Pyrex. Their coefficients of thermal expansion are of the same order of magnitude.

In the present application, the close thermal expansion coefficients of the two materials mean that the absolute value of the ratio of the difference between the two to the smaller of the two is less than 9.

In some embodiments, the redistribution layer comprises at least one layer of metal wires and through holes for interconnecting different layers of metal wires (if multiple layers of metal wires are included), the metal wires and the second bonding pads and the metal wires and the third bonding pads. The routing in the redistribution layer can realize the interconnection of the second bonding pad and the third bonding pad, the interconnection of the second bonding pad and the second bonding pad, and the interconnection of the third bonding pad and the third bonding pad.

Because the thermal expansion coefficients of the semiconductor material in the packaged component and the substrate are same or similar, after the packaging is completed, the warpage of the semiconductor packaging structure resulted from changes in temperature is relatively small, the yield and electrical and mechanical reliability of the semiconductor device are improved, and at the same time, the semiconductor substrate dissipates heat better than the conventional molding material used in conventional packaging techniques.

Further, since the redistribution layer can be formed by an existing semiconductor manufacturing process (e.g., FAB process, wafer manufacturing process). The manufacturing process is mature, and the line width and the line distance in the redistribution layer are thinner, so that the interconnection density is higher, and the area of a semiconductor packaging structure is smaller.

Specifically, the traces in the redistribution layer and the second and third pads may be formed by deposition, photolithography, and etching. The insulating material in the redistribution layer may be formed by a deposition process. Typically, the insulating material in the redistribution layer is an inorganic insulating material. The insulating material in the redistribution layer is selected from insulating materials that can be used to fabricate the wafer (e.g., can be used to fabricate dies).

In some embodiments, the coefficients of thermal expansion of the insulating material in the packaged component and the insulating material in the redistribution layer have the same thermal expansion coefficient or similar thermal expansion coefficients.

For example, the insulating material in the redistribution layer and the insulating material in the packaged component both comprise silicon dioxide or both comprise silicon nitride.

The thermal expansion characteristics of the redistribution layer and the packaged component are closer, which is further beneficial for preventing warpage of the semiconductor package structure.

When the redistribution layer and the packaged component both comprise the same insulating material, the process site for forming the packaged component can also be used for forming the redistribution layer. This further reduces the complexity of the fabrication process.

In some embodiments, the packaged component is in the state of a bare die.

In some embodiments, a single semiconductor package structure includes one packaged component. The role of the redistribution layer is only to lead out the first bonding pads on the packaged component.

In some embodiments, multiple packaged components are included in a single semiconductor package structure. At this time, the wires in the redistribution layer may function as signal interconnections between the first bonding pads of the plurality of packaged components.

In some embodiments, the at least one packaged component includes multiple packaged components equal in thickness, and the at least one groove includes multiple grooves equal in depth.

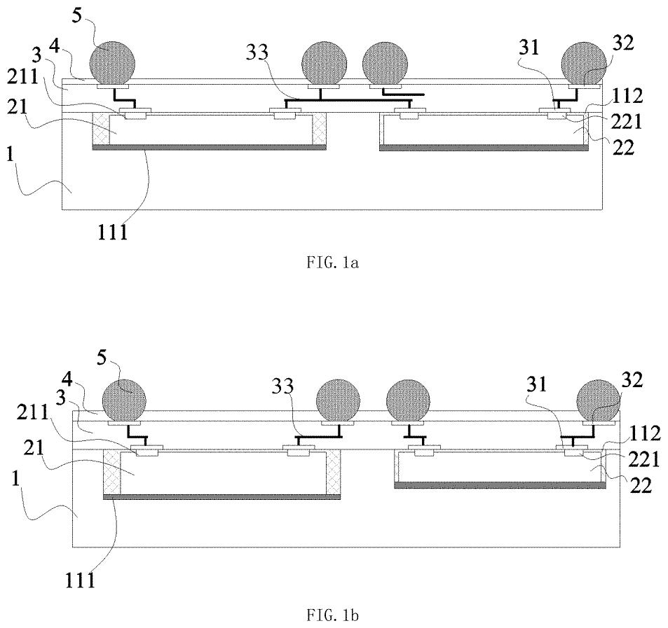

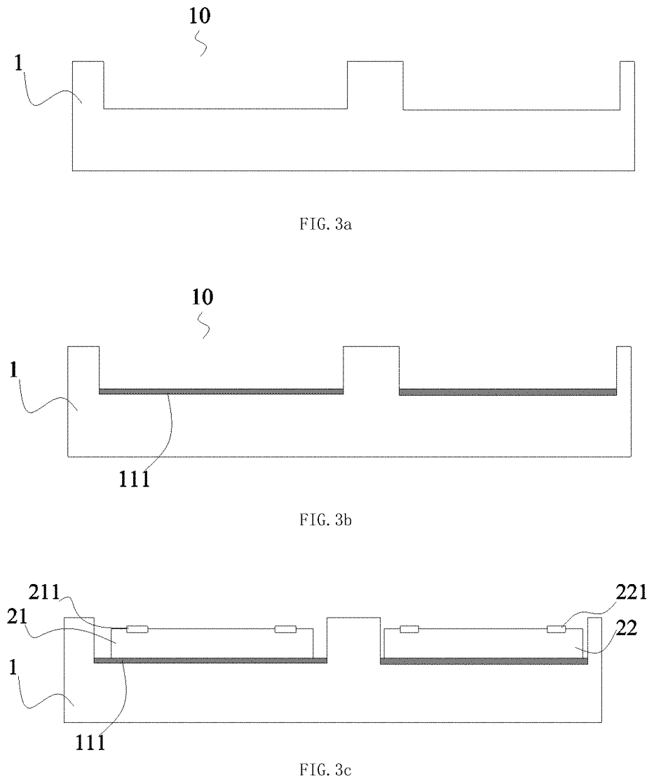

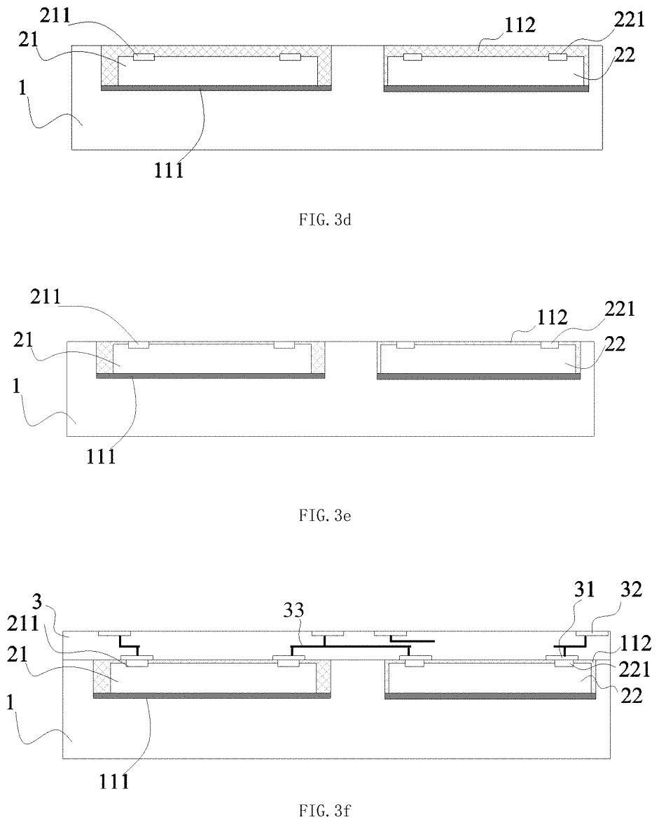

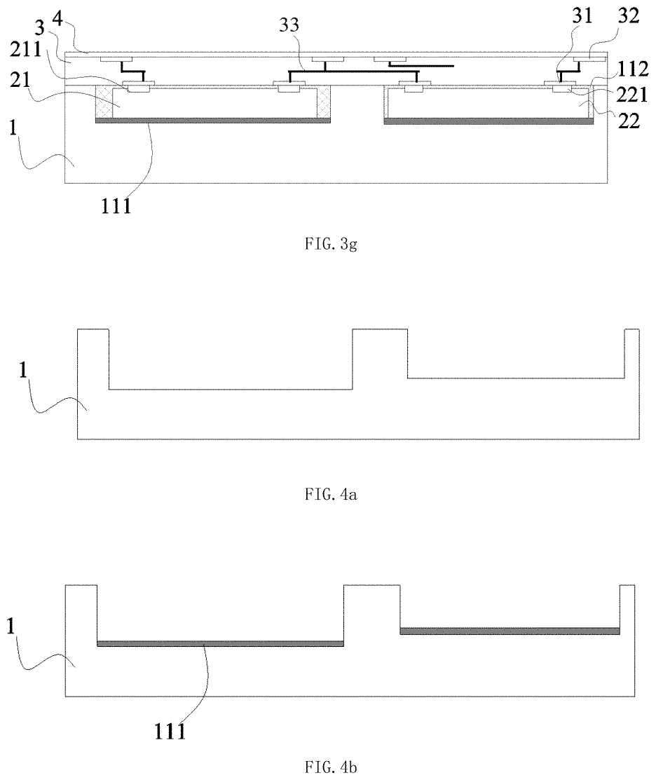

Referring to FIG. 1a and 3a, the thicknesses of the packaged component 21 and the packaged component 22 are equal, and the depths of the recesses 10 are equal.

In some embodiments, the packaged component 21 and the packaged component 22 may be the same or different. In the case that the thickness of the packaged component 21 and packaged component 22 are equal, each recess 10 can be formed using the same grooving (e.g., etching) process.

If the original thicknesses of the packaged components are not uniform, the thicknesses of the packaged components can be made equal through a thinning process.

In some embodiments, even if the original thicknesses of these packaged components 21, 22 are equal, their thicknesses can be reduced to a smaller equal thickness by a thinning process. In this manner, the groove depth of the recess 10 formed in the substrate 1 can be reduced.

In some embodiments, the at least one packaged component includes at least two packaged components, and the thicknesses of at least two packaged components are not equal, wherein the depths of at least two grooves are different, so that the upper surfaces of the first bonding pads of the packaged components are flush.

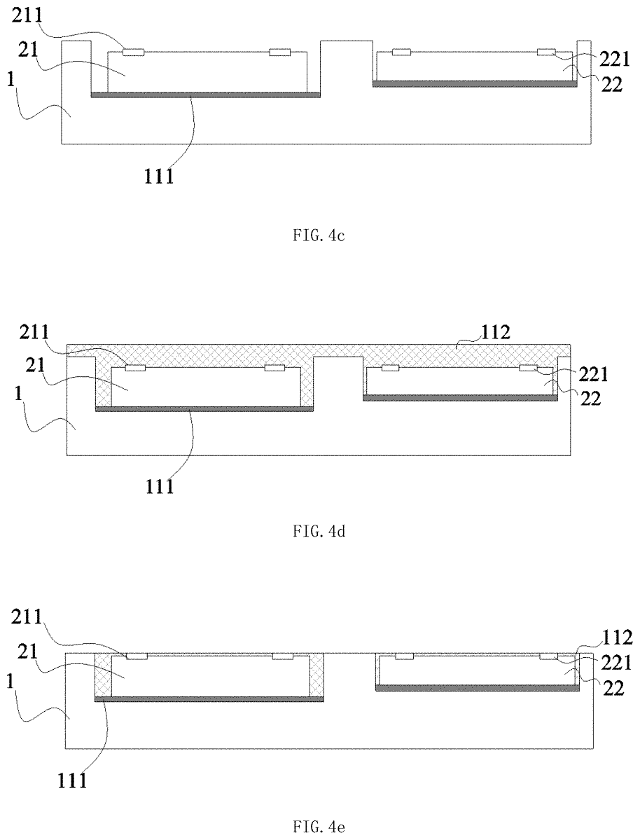

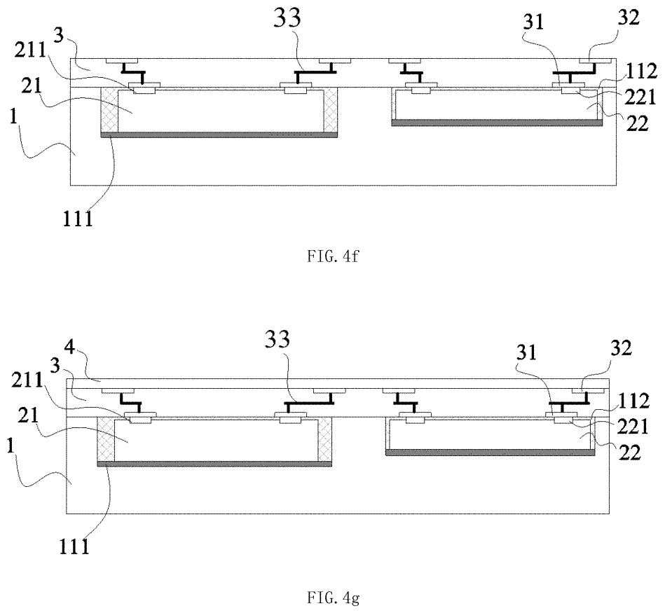

Referring to FIG. 1b and 4a, the thickness of the packaged component 21 and the packaged component 22 are not equal, nor are they equal in the depth of the recess 10. The packaged component 21 is thicker and, correspondingly, is located at a greater depth in the recess 10.

The grooves 10 of different depths can be formed by controlling the etching process used to form the grooves, such as step etching or double etching.

In some embodiments, after the passivation layer covers the third bonding pad above the redistribution layer, the semiconductor packaging structure can be used as a product for independent sale.

In some embodiments, referring to FIG. 1a and 1b, the semiconductor package structure further includes electrode structures 5 on a side of the passivation layer 4 facing away from the substrate 1. Via holes (not shown) can be opened from a side of the passivation layer 4 opposite to the side of the passivation layer facing the third pad 32. The electrode structures 5 correspond, respectively, to the third pads 32, and are respectively and electrically connected to the corresponding third pads 32 through respective via holes.

Specifically, a electrode structure 5 includes, for example, an Under Bump Metal (UBM) covering a third pad, and a solder ball located above the under bump metal. Or, the electrode structure may also be a Pad formed over the third Pad.

In some embodiments, the packaged component is separated from the groove bottom of the groove by an insulating adhesive layer. For example, the packaged component is fixed by the insulating adhesive layer, which also serves as insulation between the packaged component and the groove bottom of the groove.

In some embodiments, the packaged component is separated from the sides or side surfaces of the recess by a cured resin material (e.g., epoxy) or an inorganic insulating material. A resin material may be filled and cured into the gap between the packaged component and the side surfaces of the recess, or an inorganic insulating material (e.g., silicon dioxide) may be deposited into the gap.

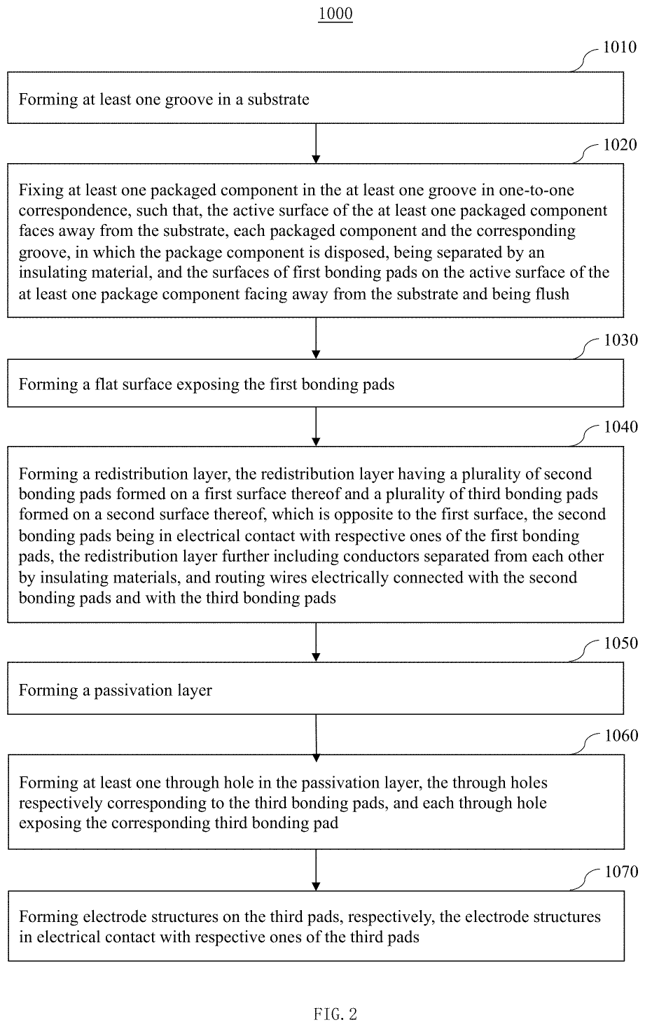

Referring to FIG. 2, some embodiments further provides a semiconductor packaging method 1000. The packaging method 1000 can be used to manufacture the semiconductor packaging structure in accordance with some embodiments. The packaging method 1000 includes steps 1010-1050, as described in the following.

Step 1010—forming at least one groove in a substrate. In some embodiments, the substrate is made of semiconductor material or insulating material, and the substrate material has the same or similar thermal expansion coefficient as the base material in a to-be-packaged or packaged component.

Step 1020—fixing at least one packaged component in the at least one groove in a one-to-one correspondence manner. In some embodiments, the active surface of the at least one packaged component faces away from the substrate, and each packaged component and the corresponding groove, in which the package component is disposed, are separated by one or more insulating materials. Each packaged component is provided with first bonding pads located on the active surface of the packaged component, and the surfaces of the first bonding pads, which faces away from the substrate, is flush.

Step 1030—forming a flat surface exposing the first bonding pads. In some embodiments, a surface treatment process such as chemical cleaning, polishing, etc. is performed to obtain a flat surface exposing the first bonding pads.

Step 1040—forming a redistribution layer using, for example, semiconductor wafer processing technologies. In some embodiments, a plurality of second bonding pads are formed on a first surface of the redistribution layer, and a plurality of third bonding pads are formed on a second surface of the redistribution layer, which is opposite to the first surface. In some embodiments, the second bonding pads are in electrical contact with respective ones of the first bonding pads, conductors in the redistribution layer are separated from each other by insulating materials, and the redistribution layer is also provided with routing wires which are electrically connected with the second bonding pads and the third bonding pads.

Step 1050—forming a passivation layer. In some embodiments, the passivation layer is formed over the redistribution layer.

In some embodiments, the semiconductor material in the substrate is the same as the base semiconductor material in the packaged component.

In some embodiments, the semiconductor material in the packaged component is silicon or gallium arsenide, and the material of the substrate is engineered Pyrex.

In some embodiments, the coefficients of thermal expansion of the insulating material in the packaged component and the insulating material in the redistribution layer are the same or similar.

For example, the insulating material in the redistribution layer and the insulating material in the packaged component both comprise silicon dioxide or both comprise polysilicon.

Because the thermal expansion coefficients of the semiconductor material in the packaged component and the substrate are the same or similar, after the packaging is completed, the warpage of the semiconductor packaging structure resulted from changes in temperature is relatively small, and the yield and electrical and mechanical reliability of the semiconductor device including the semiconductor packaging structure are improved.

Further, since the redistribution layer is formed by a semiconductor manufacturing process (FAB process). For example, deposition, photolithography, etching, etc. processes may be used to form traces and electrodes in the redistribution layer, and a layer of insulating material may be formed by the deposition process. Not only is the manufacturing process mature, but also the line width in the redistribution layer is thinner and the line distance is smaller, so that the interconnection density is higher, and the area of the semiconductor packaging structure is smaller.

Since the redistribution layer and the packaged component both include insulating materials with the same thermal expansion coefficient or similar thermal expansion coefficients, the thermal expansion characteristics of the redistribution layer and the packaged component are similar, which is further beneficial for preventing warping of the semiconductor packaging structure.

In some embodiments, the packaging method 1000 further comprises steps 1060 and 1070, as described in the following.

Step 1060—forming at least one through hole on the passivation layer. In some embodiments, the through holes respectively correspond to the third bonding pads, and the through holes expose the corresponding third bonding pads.

Step 1070—forming electrode structures on the third pads, respectively, the electrode structures in electrical contact with respective ones of the third pads.

In some embodiments, the at least one packaged component includes at least two packaged components corresponding respectively to at least two grooves of the same depth, and the packaging method 1000 further comprises: thinning at least one of the packaged components so that the packaged components have equal thickness.

In some embodiments, the at least one packaged component includes at least two packaged components of unequal thicknesses, and the depths of at least two grooves are not equal when the grooves are formed in the substrate, so that the upper surfaces of the first bonding pads of different packaged components are flush.

In some embodiments, fixing the at least one packaged component in the at least one recess in one-to-one correspondence includes: forming an insulating adhesive layer at the bottom of a groove; affixing a packaged component on the insulating adhesive, reserving a gap between the packaged component and each side surface of the groove; and filling the gap between the packaged component and each side surface of the corresponding groove with an insulating material.

In some embodiments, filling the gap between the packaged component and each side surface of the corresponding groove with an insulating material includes: filling the gap b between the packaged component and each side surface of the corresponding groove with a resin material and curing the resin material; or depositing an inorganic oxide insulating material into the gap between the packaged component and each side surface of the corresponding groove.

In some embodiments, forming a flat (or planar surface) exposing the first bonding pads includes removing the insulating material and the substrate material above the first bonding pads by a grinding process, followed by a surface treatment.

In some embodiments, the substrate can have sufficient area allowing the formation of a number of grooves. The method 1000 further comprises obtaining a plurality of semiconductor packaging structures using a dicing process. Each semiconductor packaging structure at least comprises: a packaged component, a recess in which the packaged component is located, a redistribution layer electrically connected to the packaged component, and a passivation layer over the redistribution layer.

In some embodiments, the packaged component is bare die or in the state of a bare die before being fixed in the corresponding groove.

Referring to FIGS. 3a to 3g and FIG. 1a, a specific implementation process of the packaging method 1000 to form a semiconductor device is described in accordance with some embodiments.

Referring to FIG. 3a, in step 1010, a plurality of grooves 10 are formed on a substrate 1 by an etching process, and the plurality of grooves 10 have the same depth.

Referring to FIG. 3b, an insulating adhesive layer 111 is formed at the bottom of the groove 10.

Referring to FIG. 3c, in step 1020, the packaged component 21 and the packaged component 22 are respectively placed in respective grooves 10 and adhered to the insulating adhesive 111, wherein the first bonding pads 211 of the packaged component 21 and the first bonding pads 221 of the packaged component 22 face upward (away from the substrate), and the thicknesses of the packaged component 21 and the packaged component 22 are equal. Each of packaged components 21 and 22 are spaced from the side walls of the recess 10 in which they are located.

Referring to FIG. 3d, the recess 10 is filled with the insulating material 112. For example, a liquid epoxy resin is dropped into the gap between the groove 10 and the packaged components 21 and 22, and the epoxy resin is cured by heating. Or an inorganic insulating material (for example silicon dioxide) is deposited into the gap between the recess 10 and the packaged components 21, 22.

Referring to FIG. 3e, in step 1030, portions of the insulating material 112 higher than the first bonding pads 211 and 221 and portions of the substrate material higher than the first bonding pads 211 and 221 are removed by grinding, and a surface treatment process such as chemical cleaning, polishing, etc. is performed to obtain a flat or planar surface exposing the first bonding pads 211 and 221.

Referring to FIG. 3f, in step 1040, a redistribution layer 3 is formed on the planar surface, the second electrodes 31 of the redistribution layer 3 is electrically contacted with the first bonding pads 211, 221, respectively, and the third electrodes 32 of the redistribution layer 3 is interconnected with the second electrodes 31.

Specifically, in some embodiments, the second electrodes 31 may be patterned by sputtering or electroplating, and patterning processes such as photolithography, etching, and cleaning, an insulating material layer (for example, a silicon dioxide layer) is formed by an FAB process such as deposition, a via hole exposing each second electrode 31 is formed in the insulating material layer, a trace 33 connected to the second electrode 31 is formed by sputtering or electroplating, and patterning processes, another insulating material layer is deposited; another layer of traces 33 and a layer of insulating material are formed again; then, a via hole exposing the lower trace 33 is formed in the newly obtained insulating material layer, and finally, the pattern of the third electrode 32 is formed through processes of sputtering, electroplating and patterning.

In some embodiments, the patterning process may be used to form the second pads 31 first, followed by forming the insulating material layer, forming the via hole in the insulating material layer to expose the second pad 31, and then forming the pattern of the first layer traces 33.

The redistribution layer can also be prepared by those skilled in the art using conventional technologies

In the above manner, the process of manufacturing the redistribution layer can be the same as or similar to the process of manufacturing bare chips. There are multiple layers of traces 33 in the redistribution layer.

Referring to FIG. 3g, in step 1050, a passivation layer 4 is formed on the redistribution layer 3. The passivation layer 4 may be made of silicon nitride (sin), polyimide (polyimide), or the like. The passivation layer 4 serves to protect the elements therebelow.

Referring to FIG. 1a, in step 1060, vias can be etched in the passivation layer 4 to expose the respective third electrodes 32, and, in step 1070, the electrode structures 5 are formed on the third electrodes 32. An electrode structure 5 includes, for example, Under Bump Metal (UBM) on a third electrode 32 and solder balls on the under-bump metal. The electrode structure 5 may also be in the form of a pad.

Referring to FIGS. 4a to 4g and FIG. 1b, the packaging method 1000 for manufacturing a semiconductor device can be implemented as follows in accordance with some embodiments.

Referring to FIG. 4a, in step 1010, a plurality of grooves 10 are formed on a substrate 1 by controlling a grooving process (e.g., step etching or secondary etching), wherein the plurality of grooves 10 have different depths.

Referring to FIG. 4b, an insulating adhesive layer 111 is formed at the bottom of each groove 10.

Referring to FIG. 4c, in step 1020, the packaged component 21 and the packaged component 22 are respectively placed in respective grooves 10 and adhered to the insulating adhesive 111. In some embodiments, the thicknesses of the packaged component 21 and the packaged component 22 are not equal, but the first bonding pads 211 of the packaged component 21 and the first bonding pads 221 of the packaged component 22 face upward and are flush.

Referring to FIG. 4d, an insulating material 112 is filled and cured into the recess 10. For example, a liquid epoxy resin is dropped into the gap between sidewalls of the groove 10 and the packaged components 21 and 22, and the epoxy resin is cured by heating. Or, an inorganic insulating material (for example silicon dioxide) is deposited into the gap between sidewalls of the recess 10 and the packaged components 21, 22.

Referring to FIG. 4e, in step 1030, the insulating material higher than the first bonding pads 211 and 221 and the substrate material higher than the first bonding pads 211 and 221 are removed by grinding, and a surface treatment process such as chemical cleaning, polishing, etc. is performed to obtain a flat surface exposing the first bonding pads 211 and 221.

Referring to FIG. 4f, in step 1040, a redistribution layer 3 is formed on the planar surface, the second electrodes 31 of the redistribution layer 3 are electrically contacted with the first bonding pads 211, 221, respectively, and the third electrodes 32 of the redistribution layer 3 is interconnected with the second electrodes 31.

Specifically, the second electrodes 31 may be patterned by sputtering or electroplating, and patterning processes such as photolithography, etching, and cleaning, an insulating material layer (for example, a silicon dioxide layer) is formed by an FAB process such as deposition, via holes exposing the second electrode 31 are formed in the insulating material layer, traces 33 connecting the second electrodes 31 are formed by sputtering or electroplating, and patterning processes, another insulating material layer is deposited, via holes exposing the lower traces 33 are formed in the newly obtained insulating material layer, and finally, the patterns of third electrodes 32 are obtained through sputtering or electroplating and patterning processes.

In the above manner, the process of manufacturing the redistribution layer is similar to the process of manufacturing bare chips. The redistribution layer includes at least one layer of traces 33.

Referring to FIG. 4g, in step 1050, a passivation layer 4 is formed on the redistribution layer 3. The passivation layer 4 may be made of silicon nitride (SiN), polyimide, or the like. The passivation layer 4 serves to protect the elements therebelow.

Referring to FIG. 4a, in step 1060, vias are etched in the passivation layer 4 to expose the respective third electrodes 32, and, in step 1070, the electrode structures 5 are formed on the third electrodes 32. An electrode structure 5 includes, for example, Under Bump Metal (UBM) over a third electrode 32 and a solder ball over the under bump metal. The electrode structure 5 may also be a bonding pad.

Some embodiments further provide a semiconductor device including the foregoing semiconductor package structure. The semiconductor package structure may be further processed, for example, to be combined with other semiconductor packages into an assembly or module.

Some embodiments further provide an electronic product including the foregoing semiconductor device. The electronic product can be any of various electronic products such as mobile phones, computers, servers, smartwatches, and the like.

Due to the improvement of the stability of the semiconductor packaging structure, the stability of the semiconductor devices and the electronic products is correspondingly improved.

The embodiments in the present application are described in a progressive manner, and the same and similar parts among the embodiments can correspond to each other, and each embodiment is described with focuses on the differences from the other embodiments.

The protective scope of the present application is not limited to the above-described embodiments, and it is apparent that various modifications and variations can be made to the present application by those skilled in the art without departing from the scope and spirit of the present application. It is intended that the present application also include such modifications and variations as come in the scope of the appended claims and their equivalents.

What is claimed is:

1. A semiconductor package structure, comprising: a substrate, at least one packaged component, a redistribution layer, and a passivation layer, wherein:
at least one groove is formed in the substrate;
the at least one packaged component is fixed in the at least one groove in one-to-one correspondence;
each packaged component is separated from a corresponding groove, in which the package component is disposed, by insulating materials;
the at least one packaged component has at least one active surface facing away from the substrate and first bonding pads on the at least one active surface;
surfaces of the first bonding pads facing away from the substrate are flush;
the redistribution layer is formed on one side of the at least one packaged component facing away from the substrate;
the redistribution layer has a first surface formed with a plurality of second bonding pads and a second surface opposite to the first surface and formed with a plurality of third bonding pads;
the second bonding pads are in electrical contact with respective ones of the first bonding pads;
the redistribution layer includes conductive traces separated from each other by insulating materials and routing wires electrically connected with the second bonding pads and the third bonding pads;
the passivation layer is positioned on one side of the redistribution layer facing away from the substrate; and
the substrate includes a semiconductor material or an insulating material having a thermal expansion coefficient that is the same as or similar to that of a base semiconductor material in the packaged component.

2. The semiconductor package structure of claim 1, wherein the semiconductor material in the substrate is the same as the base semiconductor material in the packaged component.

3. The semiconductor package structure of claim 1, wherein the base semiconductor material in the packaged component is silicon or gallium arsenide, and the material of the substrate is engineered Pyrex.

4. The semiconductor package structure of claim 1, wherein the coefficients of thermal expansion of an insulating material in the packaged component and an insulating material in the redistribution layer are the same or similar.

5. The semiconductor package structure of claim 4, wherein the insulating material in the redistribution layer and the insulating material in the packaged component both comprise silicon dioxide or both comprise polysilicon.

6. The semiconductor package structure of claim 1, wherein the at least one packaged component includes multiple packaged components equal in thickness, and the at least one groove includes multiple grooves equal in depth.

7. The semiconductor package structure of claim 1, wherein the at least one packaged component includes at least two packaged components of unequal thicknesses, and wherein the at least one groove includes at least two grooves of unequal depths such that upper surfaces of the first bonding pads of the at least two packaged components are flush.

8. The semiconductor package structure according to claim 1, further comprising electrode structures on a side of the passivation layer facing away from the substrate, wherein via holes are formed in the passivation layer, the electrode structures corresponding to the third pads one by one and being electrically connected to the corresponding third pads through the via holes.

9. The semiconductor package structure of claim 1, wherein the at least one packaged component includes at least one bare die.

10. The semiconductor package structure of claim 1, wherein each packaged component is separated from the bottom of a corresponding groove by an insulating adhesive layer and from side surfaces of a corresponding groove by a cured resin material or an inorganic insulating material.

11. A semiconductor packaging method, comprising:
forming at least one groove on a substrate;
fixing at least one packaged component in the at least one groove in one-to-one correspondence, wherein each packaged component is separated from a corresponding groove in which the packaged component is located by one or more insulating materials, the at least one packaged component has at least one active surface facing away from the substrate and first bonding pads on the at least one active surface, and surfaces of the first bonding pads facing away from the substrate are flush;
forming a flat surface exposing the first bonding pads;
forming a redistribution layer using a wafer manufacturing process, the redistribution layer having a first surface formed with a plurality of second bonding pads and a second surface opposite to the first surface and formed with a plurality of third bonding pads, the second bonding pads being in electrical contact with respective ones of the first bonding pads, the redistribution layer further including conductive traces separated from each other by insulating materials and routing wires electrically connected with the second bonding pads and the third bonding pads; and
forming a passivation layer;
wherein the substrate includes a semiconductor material or an insulating material, and a thermal expansion coefficient of the substrate is the same as or similar to that of a base semiconductor material in the packaged component.

12. The semiconductor packaging method of claim 11, wherein the semiconductor material in the substrate is the same as the base semiconductor material in the packaged component.

13. The semiconductor packaging method of claim 11, wherein the base semiconductor material in the packaged component is silicon or gallium arsenide, and the material of the substrate is engineered Pyrex.

14. The semiconductor packaging method of claim 11, wherein the coefficients of thermal expansion of an insulating material in the packaged component and an insulating material in the redistribution layer are the same or similar.

15. The semiconductor packaging method of claim 14, wherein the insulating material in the redistribution layer and the insulating material in the packaged component both comprise silicon dioxide or both comprise polysilicon.

16. The semiconductor packaging method of claim 11, wherein the at least one packaged component includes multiple packaged components equal in thickness, and the at least one groove includes multiple grooves equal in depth.

17. The semiconductor packaging method of claim 11, wherein the at least one packaged component includes at least two packaged components of unequal thicknesses, and the at least one groove includes at least two grooves of unequal depths such that upper surfaces of the first bonding pads of the at least two packaged components are flush.

18. The semiconductor packaging method of claim 11, wherein the at least one packaged component includes at least one bare die; and wherein fixing the at least one packaged component in one-to-one correspondence in the at least one groove comprises:
forming an insulating adhesive layer at a bottom surface of each groove;
affixing each packaged component on the insulating adhesive layer in a corresponding groove, reserving a gap between the packaged component each side surface of the corresponding groove; and
filling the gap between the packaged component and each side surface of the corresponding groove with an insulating material.

19. The semiconductor packaging method of claim 18, wherein filling the gap between the packaged component and each side surface of the corresponding groove with an insulating material comprises:
injecting and curing a resin material between the packaged component and the corresponding groove side surface, or depositing an inorganic oxide insulating material in the gap between the packaged component and the corresponding groove side surface.

20. The semiconductor packaging method of claim 11, wherein forming a planar surface exposing the first bonding pads comprises:
removing portions of the insulating material and the substrate material that are higher than the first bonding pads using a grinding process and following with surface treatment.
